(19) United States
(12) Patent Application Publication
(10) Pub. No.: US 2026/0371809 A1
(43) Pub. Date: Nov. 19, 2026

(54) LAMINATED SEMICONDUCTOR LIGHT-EMITTING ELEMENT FOR DISPLAY PIXEL, AND DISPLAY DEVICE COMPRISING SAME

(71) Applicant: LG ELECTRONICS INC., Seoul (KR)

(72) Inventors: Jeongbeom NAM, Seoul (KR); Younghak CHANG, Seoul (KR); Hyungseok BANG, Seoul (KR); Seongkyu JANG, Seoul (KR)

(73) Assignee: LG ELECTRONICS INC., Seoul (KR)

(21) Appl. No.: 19/133,941

(22) PCT Filed: Nov. 30, 2022
(86) PCT No.: PCT/KR2022/019288

§ 371 Date: May 29, 2025

(51) Int. Cl. H10H 29/34; H10H 29/80

(52) U.S. Cl. CPC H10H 29/34; H10H 29/8323

(57) ABSTRACT

A stacked semiconductor light emitting device for a display pixel according to an embodiment may include a substrate; a plurality of semiconductor light emitting devices vertically disposed on the substrate; a common electrode and individual electrodes electrically connected to the plurality of semiconductor light emitting devices; transparent conductive layers in contact with one surface of each of the plurality of semiconductor light emitting devices and connected to the individual electrodes; and a light conversion layer disposed on a lower surface of the transparent conductive layer.

### TECHNICAL FIELD

The present invention relates to a stacked semiconductor light emitting device for a display pixel and a display device including the same.

### BACKGROUND ART

Smart glasses for AR or VR require high-resolution and high-ppi displays. However, in the case of flat RGB light emitting devices, when one color is emitted, the area of the color that is not emitted appears empty, making it difficult to implement high-ppi.

Therefore, there is research on a high-ppi display device through a structure in which RGB semiconductor light emitting devices are vertically stacked on a substrate, and micro-LEDs, etc. can be used as semiconductor light emitting devices.

A micro-LED display is a display that uses micro-LEDs, which are semiconductor light emitting devices with a diameter or cross-sectional area of 100 μm or less, as display devices.

Since a micro-LED display uses micro-LEDs, which are semiconductor light emitting devices, as display devices, it has excellent performance in many characteristics such as contrast ratio, response speed, color reproducibility, viewing angle, brightness, resolution, lifespan, luminous efficiency, and brightness.

In particular, micro-LED displays have the advantage of being able to freely adjust the size and resolution by separating and combining the screen in a modular manner, and the advantage of being able to implement a flexible display.

On the other hand, in the case of small display devices such as smart glasses, it is difficult to form vias for each RGB semiconductor light emitting device in a stacked semiconductor light emitting device using ultra-small micro-LEDs, making it difficult to supply power. The present invention seeks to solve this problem.

### DISCLOSURE

### Technical Problem

The embodiment aims to solve the above-mentioned problems and other problems.

Another object of the embodiment is to provide a stacked semiconductor light emitting device for display pixels capable of implementing a high-ppi and high-resolution display and a display device including the same.

In addition, another object of the embodiment is to provide a stacked semiconductor light emitting device for display pixels capable of increasing light efficiency through light scattering and a display device including the same.

In addition, another object of the embodiment is to provide a stacked semiconductor light emitting device for display pixels capable of improving an electrical signal transmission speed and a display device including the same.

In addition, another object of the embodiment is to provide a stacked semiconductor light emitting device for display pixels capable of forming a via hole outside a semiconductor epi layer and a display device including the same.

Another object of the embodiment is to provide a stacked semiconductor light emitting device for display pixels capable of improving light extraction in a vertical direction and a display device including the same.

Another object of the embodiment is to provide a stacked semiconductor light emitting device for a display pixel capable of minimizing loss of a light-emitting area and a display device including the same.

The technical problems of the embodiment are not limited to those described in this item, and include those that can be understood throughout the specification.

### Technical Solution

A stacked semiconductor light emitting device for a display pixel according to an embodiment includes a substrate; first, second, and third semiconductor light emitting devices disposed vertically on the substrate; a common electrode electrically connected to the first, second, and third semiconductor light emitting devices; a first electrode, a second electrode, and a third electrode disposed on one side of each of the first, second, and third semiconductor light emitting devices so as not to overlap in the vertical direction and electrically connected to each of the first, second, and third semiconductor light emitting devices; first, second, and third transparent conductive layers respectively contacting one surface of each of the first, second, and third semiconductor light emitting devices and respectively connected to the first electrode, the second electrode, and the third electrode; and

The first, second, and third transparent conductive layers may include an area overlapping the first, second, and third semiconductor light emitting devices and an area not overlapping the first, second, and third semiconductor light emitting devices, and a first, second, and third light conversion layer respectively disposed on the lower surfaces of the first, second, and third transparent conductive layers.

In addition, in the embodiment, the first transparent conductive layer may extend horizontally on one side of the first semiconductor light emitting device and be connected to the first electrode,
the second transparent conductive layer may extend horizontally on one side of the second semiconductor light emitting device and be connected to the second electrode,
the third transparent conductive layer may extend horizontally on one side of the third semiconductor light emitting device and be connected to the third electrode.

In addition, in the embodiment, the first transparent conductive layer may have a larger area than the first semiconductor light emitting device.

In addition, in the embodiment, the common electrode and the first, second, and third electrodes may surround the semiconductor light emitting device.

In addition, in the embodiment, the first light conversion layer may include a light reflection layer.

In addition, in the embodiment, the second and third light conversion layers may include a light scattering layer.

In addition, in the embodiment, the first, second and third light conversion layers may include a nanowire including Ag.

In addition, in the embodiment, the common electrode includes a fourth electrode connected to the first, second and third semiconductor light emitting devices,

And the fourth electrode may be disposed on at least a portion of the other surface of the first, second and third semiconductor light emitting devices.

In addition, in the embodiment, each of the first, second and third electrodes may have different heights.

In addition, in the embodiment, the passivation layer may be further disposed on the substrate and covering the first, second and third semiconductor light emitting devices, the common electrode and the first, second and third electrodes.

### Advantageous Effects

According to the stacked semiconductor light emitting device for display pixels according to the embodiment and the display device including the same, there is a technical effect that high resolution and high-ppi can be implemented by forming a stacked structure.

In addition, the embodiment has a technical effect that electrical connection is possible without loss of the light-emitting area of the semiconductor light emitting device.

For example, a semiconductor light emitting device can be connected to an individual electrode through a transparent conductive layer disposed on the lower surface of the semiconductor light emitting device and receive an electrical signal, and there is a technical effect of increasing light-emitting efficiency without forming a via for electrical connection to the semiconductor light emitting device, thereby preventing loss of light-emitting area.

In addition, a transparent conductive layer 150 can be disposed in an area overlapping with the semiconductor light emitting device 130, thereby improving the efficiency of light emitted upward from the stacked semiconductor light emitting device.

In addition, the embodiment has a technical effect of improving light efficiency through light scattering.

For example, by disposing a light conversion layer under a transparent conductive layer, light efficiency can be improved.

In addition, the embodiment has a technical effect that an electrical signal transmission speed can be improved.

For example, since a light conversion layer disposed under a transparent conductive layer has higher electrical conductivity than the transparent conductive layer, a signal transmission speed from an electrode to a semiconductor light emitting device can be improved.

In addition, the embodiment has a technical effect that light efficiency is improved through light reflection.

For example, a light reflection layer is disposed under a transparent conductive layer connected to a semiconductor light emitting device disposed at the bottom in a stacked structure, so that light emitted downward in the stacked structure can be reflected upward, thereby improving light efficiency.

In addition, the embodiment has a technical effect that can reduce the difficulty of the process by not having to form a via hole in the semiconductor epi layer.

In addition, the embodiment has a technical effect that the electrode connected to the semiconductor light emitting device is disposed outside the light-emitting area to improve the light output, and is disposed to surround the semiconductor light emitting device on the substrate to sufficiently secure the light-emitting area to improve the brightness.

In addition, the embodiment has a special technical effect that the electrode layer disposed in an area that does not overlap with the semiconductor light emitting device 130 is disposed with a transparent conductive layer 150 to prevent back reflection of light emitted upward from the stacked semiconductor light emitting device, thereby significantly improving the brightness.

The technical effects of the embodiment are not limited to those described in this item, and include those that can be understood throughout the entire specification.

### DESCRIPTION OF DRAWINGS

FIG. 1 is a perspective view of a stacked semiconductor light emitting device for a display pixel according to an embodiment.

FIG. 2 is a conceptual diagram of a stacked semiconductor light emitting device for a display pixel according to an embodiment.

FIG. 3 is a cross-sectional view showing in detail the structure of the semiconductor light emitting device shown in FIG. 2.

FIGS. 4A to 4G are process diagrams of a stacked semiconductor light emitting device for a display pixel according to an embodiment.

### MODE FOR INVENTION

Hereinafter, the embodiments disclosed in this specification will be described in detail with reference to the attached drawings. The suffixes ‘module’ and ‘part’ used for components in the following description are given or used interchangeably in consideration of the ease of writing the specification, and do not have distinct meanings or roles in themselves. In addition, the attached drawings are intended to facilitate easy understanding of the embodiments disclosed in this specification, and the technical ideas disclosed in this specification are not limited by the attached drawings. In addition, when an element such as a layer, area, or substrate is mentioned as existing ‘on’ another element, this includes that it may be directly on the other element, or that other intermediate elements may exist between them.

The semiconductor light emitting device described in this specification may include smart glasses, digital TVs, mobile phones, smart phones, laptop computers, digital broadcasting terminals, PDAs (personal digital assistants), PMPs (portable multimedia players), navigation, slate PCs, tablet PCs, Ultra-Books, desktop computers, etc. However, the configuration according to the embodiment described in this specification may also be applied to a device capable of displaying, even if it is a new product type developed in the future.

Hereinafter, a stacked semiconductor light emitting device for a display pixel including a semiconductor light emitting device according to an embodiment will be described.

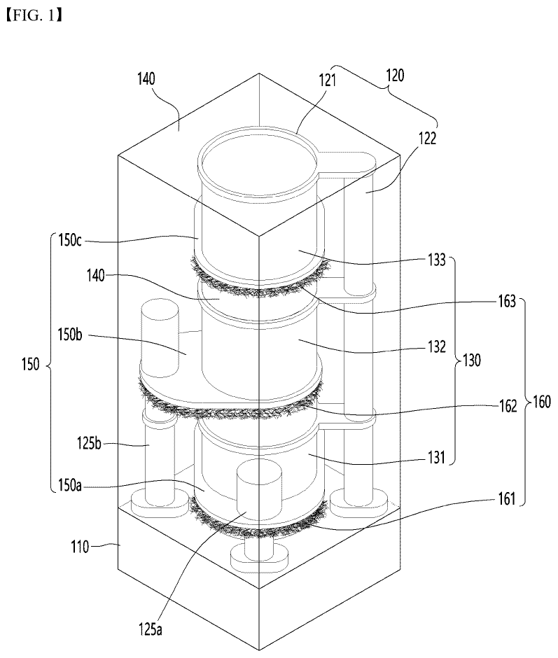

FIG. 1 is a perspective view of a stacked semiconductor light emitting device for a display pixel according to an embodiment (hereinafter referred to as a ‘stacked semiconductor light emitting device’). In the embodiment, the semiconductor light emitting device may be a micro-LED or a nano-LED, but is not limited thereto.

Referring to FIG. 1, a semiconductor light emitting device 130 may be disposed on a substrate 110. The semiconductor light emitting device 130 may include first, second, and third semiconductor light emitting devices 131, 132, 133, and may be formed in a cylindrical shape, but is not limited thereto. The first, second, and third semiconductor light emitting devices 131, 132, 133 may be vertically stacked. In addition, a common electrode 120 and a first electrode 125a, a second electrode 125b, and a third electrode 125c (not shown) may be disposed on the substrate 110. In addition, the substrate 110 may be provided with a CMOS to drive the semiconductor light emitting device, and may be formed of silicon, etc.

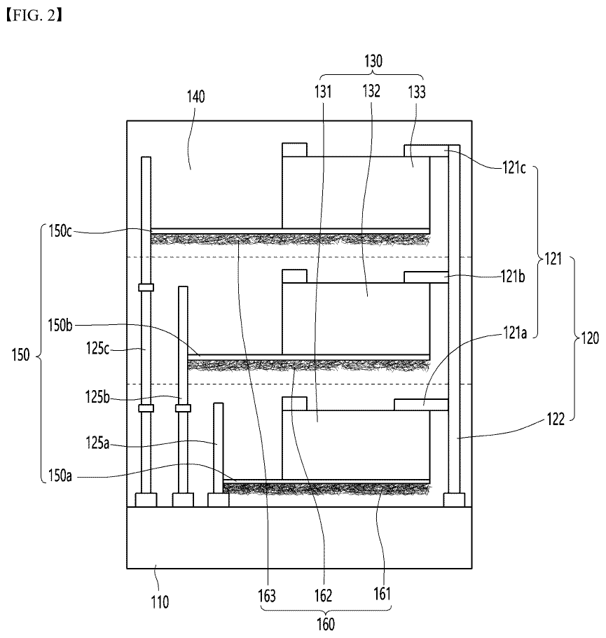

The semiconductor light emitting device 130 may be electrically connected to the common electrode 120. The common electrode 120 may commonly supply power to the first to third semiconductor light emitting devices 131, 132, 133. The first semiconductor light emitting device 131 may be electrically connected to the first electrode 125a. The second semiconductor light emitting device 132 may be electrically connected to the second electrode 125b. The third semiconductor light emitting device 133 may be electrically connected to the third electrode 125c (see FIG. 2). The common electrode 120 and the first, second, and third electrodes 125a, 125b, 125c may be electrically connected to a CMOS provided in the substrate 110 to drive the semiconductor light emitting devices.

An insulating layer 140 may be disposed under the first, second, and third semiconductor light emitting devices 131, 132, 133. The insulating layer may be formed of SiO₂, but is not limited thereto. The insulating layer 140 prevents electrical shorts between each semiconductor light emitting device and has adhesive strength to stabilize the stacked structure. In addition, it has a technical effect of absorbing heat generated from the semiconductor light emitting device 130 to perform a heat dissipation function of the semiconductor light emitting device.

Meanwhile, according to an internal study on the stacked semiconductor light emitting device, the existing stacked semiconductor light emitting device vertically stacks light emitting devices that emit R, G, and B colors, and then electrically connects them by forming a via in the epi layer of each light emitting device.

However, in display devices such as VR, AR, and MR that require high-ppi and high resolution, ultra-small semiconductor light emitting devices are used, and in the case of ultra-small micro-LEDs, they have a size that is so small that it is difficult to form a via in the epi layer. In addition, since the material of the epi layer is different depending on the color that is emitted, the etching conditions are different, making it difficult to form a via hole. Therefore, research on an electrical connection method other than an electrical connection through a via hole in a stacked semiconductor light emitting device is required.

Again, referring to FIG. 1, the first, second, and third electrodes 125a, 125b, 125c can be electrically connected to the first, second, and third semiconductor light emitting devices 131, 132, 133 through the first, second, and third transparent conductive layers 150a, 150b, 150c.

According to the embodiment, the semiconductor light emitting device 130 for display pixels is electrically connected to the substrate through the common electrode 120 and the first, second, and third electrodes 125a, 125b, 125c and the transparent conductive layer 150, so there is no need to form a via hole, so there is no area loss of the epi layer, and the reliability of the epi layer is improved because the via process is not performed on the epi layer, resulting in a composite technical effect.

In the embodiment, the transparent conductive layer 150 may include an area overlapping the semiconductor light emitting device 130 and an area extending outside the semiconductor light emitting device 130 and not overlapping the semiconductor light emitting device 130.

Accordingly, according to the embodiment, a high resolution and high-ppi are realized by forming a stacked structure, and at the same time, unlike in the prior art, the lower electrode layer is disposed on the outside so as not to overlap with the semiconductor light emitting device 130, thereby enabling electrical connection without loss of the light-emitting area.

In addition, in the embodiment, a transparent conductive layer 150 is disposed in the area overlapping with the semiconductor light emitting device 130, thereby improving the efficiency of light emitted upward from the stacked semiconductor light emitting device.

In addition, in the embodiment, unlike in the prior art, a transparent conductive layer 150 is disposed in the electrode layer that is disposed in the area not overlapping with the semiconductor light emitting device 130, thereby preventing back reflection of light emitted upward from the stacked semiconductor light emitting device, thereby providing a special technical effect of significantly enhancing brightness.

Meanwhile, a light conversion layer 160 may be disposed on the lower surface of the transparent conductive layer 150. The light conversion layer 160 may include a first light conversion layer 161, a second light conversion layer 162, and a third light conversion layer 163, and may be electrically connected to the first semiconductor light emitting device 131, the second semiconductor light emitting device 132, and the third semiconductor light emitting device 133 through the first transparent conductive layer 150a, the second transparent conductive layer 150b, and the third transparent conductive layer 150c, respectively.

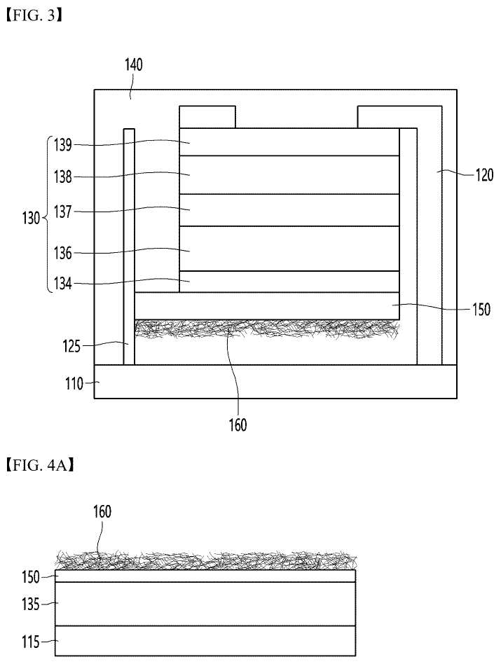

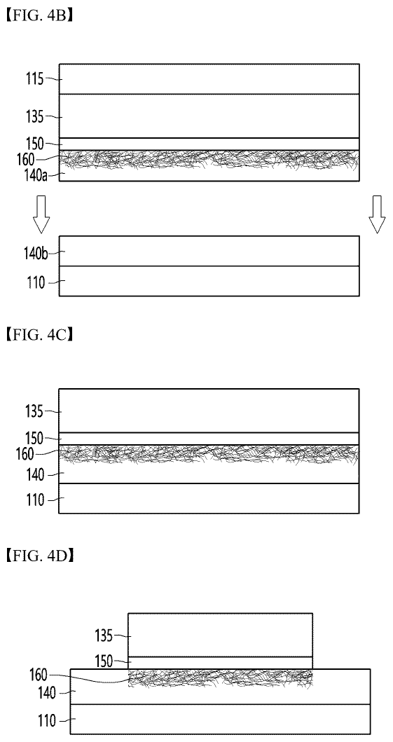

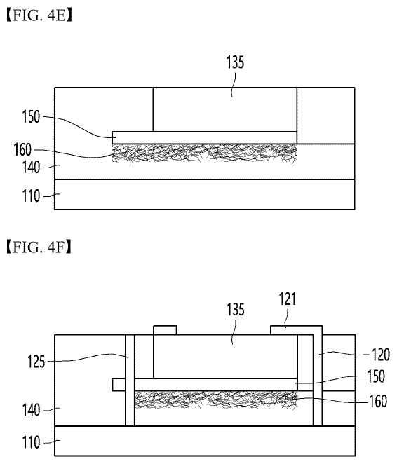

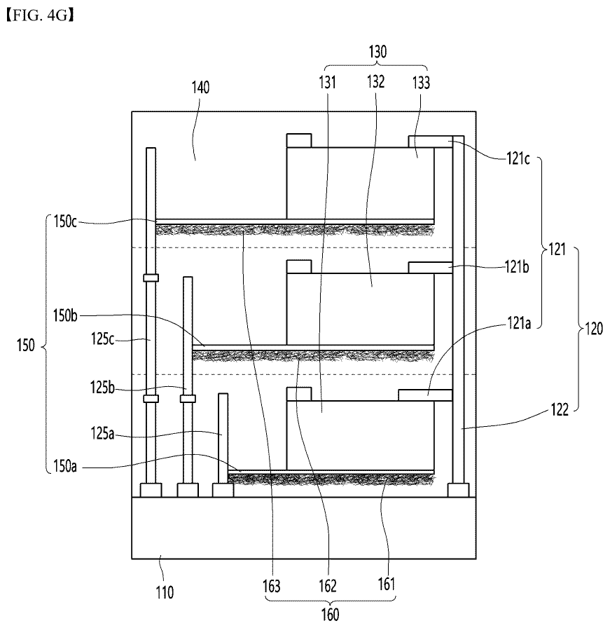

The light conversion layer 160 may be formed in a nanowire structure. The light conversion layer 160 may have a lower electrical resistance than the transparent conductive layer 150. This will be described in detail in FIG. 4A.

Meanwhile, in the embodiment, there is a technical feature that the optical characteristics vary depending on the content of Ag nanowires in the light conversion layer 160. Specifically, when the content of Ag nanowires is small, the optical transmittance increases and the optical scattering rate may increase. In addition, when the content of Ag nanowires increases, the optical transmittance decreases and the optical reflectance may increase. Therefore, in the embodiment, the light conversion layer 160 can obtain specific optical characteristics by adjusting the content of Ag nanowires.

In addition, when power is supplied to the semiconductor light emitting device from the first, second, and third electrodes 125a, 125b, 125c, power can be supplied through the light conversion layer 160. Therefore, the stacked semiconductor light emitting device for display pixels according to the embodiment and the display device including the same have the technical effect of improving the electrical signal transmission speed through the light conversion layer.

In addition, the common electrode 120 and the first, second, and third electrodes 125a, 125b, 125c can be disposed to surround the semiconductor light emitting device 130. Accordingly, there is the technical effect of securing the maximum light-emitting area of the semiconductor light emitting device disposed on the substrate 110. In addition, there is the technical effect of minimizing electrical interference between the electrodes.

In addition, the transparent conductive layer 150 can be formed of, for example, ITO (Indium tin oxide), etc. Since the conductive layer through which light emitted from the bottom of the semiconductor light emitting device of the stacked structure passes is transparent and has transmittance, there is a technical effect of increasing the light traveling upward.

Meanwhile, the first light conversion layer 161 may have a higher content of Ag nanowires than the second and third light conversion layers 162, 163. The first light conversion layer 161 having a high content of Ag nanowires may have low light transmittance and high light reflectivity. In addition, the second and third light conversion layers 162, 163 having a low content of Ag nanowires may have high light transmittance and high light scattering rate.

The second light conversion layer 162 and the third light conversion layer 163 disposed on the lower surface of the second transparent conductive layer 150b and the third transparent conductive layer 150c may be used as light scattering layers. Accordingly, there is a technical effect of improving light efficiency in a display device including a semiconductor light emitting device having a stacked structure.

In detail, when light is extracted from the first semiconductor light emitting device 131, it can be emitted upward through the second light conversion layer 162. At this time, the emitted light is scattered by the second light conversion layer 162, and light efficiency can be improved.

In addition, when light is extracted from the first and second semiconductor light emitting devices 131, 132, it can pass through the third light conversion layer 163 and head upward. The light is scattered by the third light conversion layer 163, and light efficiency can be improved. Therefore, the embodiment has a technical effect of improving light efficiency as the second and third light conversion layers 162, 163 are used as light scattering layers.

In addition, the first light conversion layer 161 disposed on the lower surface of the first transparent conductive layer 161 can be used as a light reflection layer. In detail, when light is extracted from the first, second, and third semiconductor light emitting devices 131, 132, 133, light heading downward can be reflected upward by the first light conversion layer 161. Accordingly, the embodiment has a technical effect of improving light extraction efficiency as the first light conversion layer 161 is used as a light reflection layer.

Meanwhile, the semiconductor light emitting device 130, the common electrode 120, and the first, second, and third electrodes 125a, 125b, 125c disposed on the substrate may be surrounded by a passivation layer 140. The passivation layer 140 may protect the semiconductor light emitting device 130, the common electrode 120, and the first, second, and third electrodes 125a, 125b, 125c from external impact and prevent an electrical short circuit from occurring. The passivation layer 140 may be formed of SiO₂, but is not limited thereto.

FIG. 2 is a conceptual diagram of a stacked semiconductor light emitting device according to an embodiment.

Referring to FIG. 2, a stacked semiconductor light emitting device 130 including first to third semiconductor light emitting devices 131, 132, 133 may be disposed on a substrate 110. In addition, an individual electrode 125 and a common electrode 120 may be disposed on the substrate 110. The individual electrode 125 may include a first electrode 125a, a second electrode 125b, and a third electrode 125c. The semiconductor light emitting device 130 may be connected to the individual electrode 125 and the common electrode 120 through a transparent conductive layer 150.

The transparent conductive layer 150 may include a first transparent conductive layer 150a, a second transparent conductive layer 150b, and a third transparent conductive layer 150c.

The first semiconductor light emitting device 131 can be electrically connected to the first electrode 125a through the first transparent conductive layer 150a. The second semiconductor light emitting device 132 can be electrically connected to the second electrode 125b through the second transparent conductive layer 150b. The third semiconductor light emitting device 133 can be electrically connected to the third electrode 125c through the third transparent conductive layer 150c.

In addition, a light conversion layer 160 can be disposed on the lower surface of the transparent conductive layer 150. A first light conversion layer 161 may be disposed on the lower surface of the first transparent conductive layer 150a, a second light conversion layer 162 may be disposed on the lower surface of the second transparent conductive layer 150b, and a third light conversion layer 163 may be disposed on the lower surface of the third transparent conductive layer 150c.

The light conversion layer 160 may be formed to have lower resistance than the transparent conductive layer 150. For example, the light conversion layer 160 may be formed of nanowires and may be formed of Ag, but is not limited thereto.

Meanwhile, the first semiconductor light emitting device 131 may be a semiconductor light emitting device that emits red color, the second semiconductor light emitting device 132 may be a semiconductor light emitting device that emits green color, and the third semiconductor light emitting device 133 may be a semiconductor light emitting device that emits blue color, but is not limited thereto.

At this time, the first, second, and third electrodes 125a, 125b, 125c may be formed to have different heights. The transparent conductive layer 150 is formed of a light-transmitting material, and can minimize the loss of light when light generated from a semiconductor light emitting device located below is directed upward, and has the technical effect of electrically connecting the first, second, and third electrodes 125a, 125b, 125c and the first, second, and third semiconductor light emitting devices 131, 132, 133.

And, in the embodiment, the fourth electrode 121 may be formed on a part of the upper surface of the semiconductor light emitting device 130 so as to correspond to the shape of the upper surface thereof. For example, when the semiconductor light emitting device 130 has a cylindrical shape, the fourth electrode 121 may have a ring-shaped shape.

The fourth electrode 121 may include fourth-first to fourth-third electrodes 121a, 121b, 121c electrically connected to each of the first, second, and third semiconductor light emitting devices 131, 132, 133.

For example, the first semiconductor light emitting device 131 can be electrically connected to the common electrode 120 through the fourth-first electrode 121a, the second semiconductor light emitting device 132 can be electrically connected to the common electrode 120 through the fourth-second electrode 121b, and the third semiconductor light emitting device 133 can be electrically connected to the common electrode 120 through the fourth-third electrode 121c.

Next, FIG. 3 is a drawing showing in detail a semiconductor light emitting device in a stacked semiconductor light emitting device for a display pixel according to an embodiment. The following description may be applied to the first, second, and third semiconductor light emitting devices 131, 132, 133.

Referring to FIG. 3, the semiconductor light emitting device 130 may include a first conductive semiconductor layer 136, a second conductive semiconductor layer 138, and an active layer 137 disposed therebetween. The first conductive semiconductor layer 136 may be an n-type semiconductor layer, and the second conductive semiconductor layer 138 may be a p-type semiconductor layer, but is not limited thereto.

The active layer 137 is an area that generates light and can generate light having a specific wavelength band depending on the material properties of the compound semiconductor. That is, the wavelength band can be determined by the energy band gap of the compound semiconductor included in the active layer 137. Therefore, the semiconductor light emitting device 130 of the embodiment can generate UV light, blue light, green light, and red light depending on the energy band gap of the compound semiconductor included in the active layer 157.

The first conductive semiconductor layer 156, the active layer 157, and the second conductive semiconductor layer 158 may be formed of a compound semiconductor material. For example, the compound semiconductor material may be a group III-V compound semiconductor material, a group II-VI compound material, etc. For example, the compound semiconductor material may include GaN, InGaN, AlN, AlInN, AlGaN, AlInGaN, InP, GaAs, GaP, GaInP, etc.

In addition, the first electrode layer 134 may be disposed under the first conductive semiconductor layer 136, and the second electrode layer 139 may be disposed on the second conductive semiconductor layer 138. The first electrode layer 134 may be electrically connected to one of the first, second, and third electrodes through the transparent conductive layer 150 and the light conversion layer 160, and the second electrode layer 139 may be electrically connected to the common electrode 120.

FIGS. 4A to 4G are manufacturing process diagrams of a stacked semiconductor light emitting device for a display pixel according to an embodiment.

Referring to FIG. 4A, an epi layer 135 may be grown on a growth substrate 115. The epi layer 135 may be made of a compound semiconductor material. For example, the compound semiconductor material may be a group III-V compound semiconductor material, a group II-VI compound material, etc. For example, the compound semiconductor material may include GaN, InGaN, AlN, AlInN, AlGaN, AlInGaN, InP, GaAs, GaP, GaInP, etc.

A transparent conductive layer 150 may be formed on the epi layer. The transparent conductive layer 150 is formed of a light-transmitting material and may have electrical conductivity. The transparent conductive layer 150 may be formed of, for example, ITO (Indum Tin Oxide), but is not limited thereto.

Next, a light conversion layer 160 may be formed on the light-transmitting conductive layer 150. In detail, a dispersion solution including Ag may be applied on the light-transmitting conductive layer 150 by spin coating, and then soft baking may be performed. The dispersion solution may include nano-scale Ag wires. Then, when photonic welding is performed on the light-transmitting conductive layer 150 at about 300 °C, the light-transmitting conductive layer is attached to the light-transmitting conductive layer and may be formed in the form of nano-sized wires. The formed light conversion layer may have excellent current diffusion characteristics compared to the light-transmitting conductive layer.

Meanwhile, the light conversion layer 160 formed on the light-transmitting conductive layer 150 can be formed by varying the content of Ag nanowires. The light conversion layer 160 can have different optical characteristics depending on the content of Ag nanowires. Specifically, when the content of Ag nanowires is low, the light transmittance increases and the light scattering rate can increase. In addition, when the content of Ag nanowires increases, the light transmittance decreases and the light reflectance can increase. Therefore, the light conversion layer 160 can obtain specific optical characteristics by adjusting the content of Ag nanowires.

Accordingly, the embodiment has a technical effect that the electric signal transmission speed to the semiconductor light emitting device can be improved by forming the light conversion layer in the form of nanowires including Ag. In addition, there is a complex technical effect that the light efficiency can be improved by directing the light generated from the semiconductor light emitting device upward.

Referring to FIG. 4B, a first-first insulating layer 140a may be disposed under the light conversion layer 160. Then, a first-second insulating layer 140b may be formed and prepared on a substrate 110 on which a CMOS is formed. The first-first insulating layer 140a disposed under the light conversion layer 160 and the first-second insulating layer 140b disposed on the substrate 110 may be bonded so as to face each other. The first-first and first-second insulating layers 140a, 140b may be SiO₂, but are not limited thereto. Bonding of SiO₂ and SiO₂ originally requires a high temperature process of about 700 °C, but plasma treatment can be performed on the surfaces of the first and second insulating layers 140a1, 140b, and thus the bonding process can be performed at a temperature of about 400 °C, thereby preventing damage to the epi layer 135 due to high temperature.

Referring to FIG. 4C, a process of removing the growth substrate 115 is then performed. In the case of a semiconductor light emitting device that emits blue or green color, the epi layer 135 may be formed of GaN, etc., and the growth substrate may be removed through a laser lift-off method (LLO), but is not limited thereto. In the case of a semiconductor light emitting device that emits red color, the epi layer 135 may be formed of GaAs, etc., and the growth substrate may be removed through a chemical lift-off method (CLO), but is not limited thereto.

Referring to FIG. 4D, a hard mask (not shown) may be deposited on the epi layer 135 and a photo process and an etching process may be performed. The transparent conductive layer 150 may be formed in an oval shape.

Referring to FIG. 4E, a hard mask (not shown) may be deposited on an epi layer 135 and a photo process and an etching process may be performed. The epi layer 135 may be etched into an oval shape. The epi layer may be formed to have a smaller area than the transparent conductive layer 150. Then, the exposed transparent conductive layer 150 and the epi layer 135 are covered with an insulating layer. Then, the planarization may be performed through a CMP process.

Referring to FIG. 4F, a first via hole may be formed from the surface of the insulating layer 140 through the transparent conductive layer 150 to the surface of the substrate 110, and a second via hole may be formed from the surface of the insulating layer to the upper surface of the substrate so as not to overlap the semiconductor light emitting device 135 and the transparent conductive layer 150.

An individual electrode 125 may be formed in the first via hole. The individual electrode 125 may be electrically connected to the semiconductor light emitting device 135 through the transparent conductive layer 150. In addition, the individual electrode 125 may be electrically connected to the semiconductor light emitting device 135 through the light conversion layer 160 disposed on the lower surface of the transparent conductive layer 150.

The light conversion layer 160 may be formed in the form of Ag nanowires, but is not limited thereto. Accordingly, since the light conversion layer 160 may have lower resistance than the transparent conductive layer 150, there is a technical effect that the speed of electrical signal transmission from the individual electrode 125 to the semiconductor light emitting device 135 may be improved.

Next, a common electrode 120 may be formed in the second via hole. The common electrode 120 may be electrically connected to the semiconductor light emitting device 135 through the fourth electrode 121. The fourth electrode may be formed in the shape of an edge of the upper surface of the semiconductor light emitting device 135, for example, a ring shape, but is not limited thereto.

The above manufacturing process can be repeated to manufacture a semiconductor light emitting device having a stacked structure of FIG. 4G.

Referring to FIG. 4G, a second semiconductor light emitting device 132 can be disposed on a first semiconductor light emitting device 131, and a third semiconductor light emitting device 133 can be disposed on the second semiconductor light emitting device 132.

The first semiconductor light emitting device 131 can be connected to a first electrode 125a through a first transparent conductive layer 150a. In addition, a first light conversion layer 161 can be disposed on a lower surface of the first transparent conductive layer 150a.

The second semiconductor light emitting device 132 can be connected to a second electrode 125b through a second transparent conductive layer 150b. In addition, a second light conversion layer 162 may be disposed on the lower surface of the second transparent conductive layer 150b.

The third semiconductor light emitting device 133 may be connected to the third electrode 125c through the third transparent conductive layer 150c. In addition, a third light conversion layer 163 may be disposed on the lower surface of the third transparent conductive layer 150c.

At this time, the second light conversion layer 162 and the third light conversion layer 163 can be used as light scattering layers. Accordingly, the second light conversion layer 162 can scatter light emitted from the first semiconductor light emitting device 131 and increase the amount of light escaping upward. In addition, the third light conversion layer 163 can scatter light emitted from the first and second semiconductor light emitting devices 131, 132 and increase the amount of light escaping upward.

Therefore, the embodiment has a technical effect of increasing light efficiency in a semiconductor light emitting device of a stacked structure as the light conversion layer disposed on the lower surface of the transparent conductive layer is used as a light scattering layer.

In addition, the first light conversion layer 161 can be used as a light reflection layer. The first light conversion layer 161 can increase the amount of light that escapes upward by reflecting light emitted downward from the first semiconductor light emitting device 131. Therefore, the embodiment has a technical effect of increasing light efficiency in a semiconductor light emitting device of a stacked structure since the light conversion layer disposed on the lower surface of the transparent conductive layer is used as a light reflection layer. In particular, when the first semiconductor light emitting device 131 emits red color, the light efficiency is low, but the light efficiency can be improved to correspond to a semiconductor light emitting device that emits blue or green color through the light reflection layer.

According to the stacked semiconductor light emitting device for display pixels according to the embodiment and the display device including the same, there is a technical effect that high resolution and high-ppi can be implemented by forming a stacked structure.

In addition, the embodiment has a technical effect that electrical connection is possible without loss of the light-emitting area of the semiconductor light emitting device.

For example, a semiconductor light emitting device can be connected to an electrode through a transparent conductive layer disposed on the lower surface to receive an electrical signal, and there is a technical effect of increasing light-emitting efficiency without forming a via for electrical connection to the semiconductor light emitting device, thereby preventing loss of a light-emitting area.

In addition, a transparent conductive layer 150 can be disposed in an area overlapping with a semiconductor light emitting device 130, thereby improving the efficiency of light emitted upward from a stacked semiconductor light emitting device.

In addition, the embodiment has a technical effect of improving light efficiency through light scattering.

For example, by arranging a light conversion layer under a transparent conductive layer, light efficiency can be improved.

In addition, the embodiment has a technical effect that an electrical signal transmission speed can be improved.

For example, since a light conversion layer disposed under a transparent conductive layer has higher electrical conductivity than the transparent conductive layer, a signal transmission speed from an electrode to a semiconductor light emitting device can be improved.

In addition, the embodiment has a technical effect that light efficiency is improved through light reflection.

For example, a light reflection layer is disposed under a transparent conductive layer connected to a semiconductor light emitting device disposed at the bottom in a stacked structure, so that light emitted downward from the stacked structure can be reflected upward, thereby improving light efficiency.

In addition, the embodiment has a technical effect of reducing the difficulty of the process by not having to form a via hole in the semiconductor epi layer.

In addition, the embodiment has a technical effect of improving the light output by arranging the electrode connected to the semiconductor light emitting device outside the light-emitting area, and sufficiently securing the light-emitting area by arranging it to surround the semiconductor light emitting device on the substrate, thereby improving the brightness.

In addition, in the embodiment, the electrode layer disposed in an area that does not overlap with the semiconductor light emitting device 130 is also disposed with a transparent conductive layer 150, thereby preventing retroreflection of light emitted upward from the stacked semiconductor light emitting device, thereby significantly enhancing brightness, which has a special technical effect.

The above detailed description should not be construed as limiting in all aspects and should be considered as illustrative. The scope of the embodiment should be determined by a reasonable interpretation of the appended claims, and all changes within the equivalent scope of the embodiment are included in the scope of the embodiment.

### EXPLANATION OF CITED REFERENCE

110: substrate
115: growth substrate
120: common electrode
121: Fourth electrode
121a: Fourth-first electrode
121b: Fourth-second electrode
121c: Fourth-third electrode
125a: First electrode
125b: Second electrode
125c: Third electrode
130: Semiconductor light emitting device
131: First semiconductor light emitting device
132: Second semiconductor light emitting device
133: Third semiconductor light emitting device
134: First electrode layer
135: Epi layer
136: First conductive semiconductor layer
137: Active layer
138: Second conductive semiconductor layer
139: Second electrode layer
140: Passivation layer (insulating layer)
141a: First-first insulating layer
141b: First-second insulating layer
150: Transparent conductive layer
150a: First transparent conductive layer
150b: Second transparent conductive layer
160: Light conversion layer
161: First light conversion layer
162: Second light conversion layer
163: Third light conversion layer

1. A stacked semiconductor light emitting device for a display pixel comprising:
a substrate;
a first semiconductor light emitting device, a second semiconductor light emitting device, a third semiconductor light emitting device disposed on the substrate;
a common electrode electrically connected to the first, second and third semiconductor light emitting devices;
a first electrode, a second electrode and a third electrode disposed to be spaced apart from each other on one side so as not to overlap vertically with the first, second and third semiconductor light emitting devices, and electrically connected to each of the first, second and third semiconductor light emitting devices; and
a first transparent conductive layer, a second transparent conductive layer, a third transparent conductive layer respectively in contact with one surface of the first, second and third semiconductor light emitting devices and connected to the first, second and third electrodes, respectively,
wherein the first, second and third transparent conductive layers comprise areas overlapping with the first, second and third semiconductor light emitting devices and the areas are configured not to overlap with the first, second and third semiconductor light emitting devices, and
comprising a first light conversion layer, a second light conversion layer and a third light conversion layer disposed on lower surfaces of the first, second and third transparent conductive layers.

2. The stacked semiconductor light emitting device for a display pixel according to claim 1, wherein the first transparent conductive layer is configured to extend horizontally from one surface of the first semiconductor light emitting device and is connected to the first electrode,
wherein the second transparent conductive layer is configured to extend horizontally from one surface of the second semiconductor light emitting device and is connected to the second electrode, and
wherein the third transparent conductive layer is configured to extend horizontally from one surface of the third semiconductor light emitting device and is connected to the third electrode.

3. The stacked semiconductor light emitting device for a display pixel according to claim 1, wherein the first transparent conductive layer has a larger area than the first semiconductor light emitting device.

4. The stacked semiconductor light emitting device for a display pixel according to claim 1, wherein the common electrode and the first, second and third electrodes are configured to surround the semiconductor light emitting device.

5. The stacked semiconductor light emitting device for a display pixel according to claim 1, wherein the first light conversion layer comprises a light reflection layer.

6. The stacked semiconductor light emitting device for a display pixel according to claim 1, wherein the second and third light conversion layers comprise light scattering layers.

7. The stacked semiconductor light emitting device for a display pixel according to claim 1, wherein the first, second and third light conversion layers comprise nanowires configured to contain Ag.

8. The stacked semiconductor light emitting device for a display pixel according to claim 1, wherein the common electrode comprises a fourth electrode connected to the first, second and third semiconductor light emitting devices, and
wherein the four the electrode is disposed on at least a portion of other surfaces of the first, second and third semiconductor light emitting devices.

9. The stacked semiconductor light emitting device for a display pixel according to claim 1, wherein the first, second and third electrodes each are configured to have different heights.

10. The stacked semiconductor light emitting device for a display pixel according to claim 1, further comprising a passivation layer disposed on the substrate and covering the first, second and third semiconductor light emitting devices, the common electrode and the first, second and third electrodes.

11. The stacked semiconductor light emitting device for a display pixel according to claim 7, wherein the first light conversion layer has a higher content of nanowires containing Ag than the second and third light conversion layers.

12. The stacked semiconductor light emitting device for a display pixel according to claim 1, wherein an area of the first semiconductor light emitting device is same with an area of the second semiconductor light emitting device.

13. The stacked semiconductor light emitting device for a display pixel according to claim 1, wherein an area of the first semiconductor light emitting device is same with an area of the third semiconductor light emitting device.

14. The stacked semiconductor light emitting device for a display pixel according to claim 13, wherein an area of the second semiconductor light emitting device is same with an area of the third semiconductor light emitting device.

15. The stacked semiconductor light emitting device for a display pixel according to claim 1, wherein distances between the first, second, and third electrodes from a center of the first semiconductor light emitting device are the same.

16. The stacked semiconductor light emitting device for a display pixel according to claim 1, wherein the first, second and third electrodes are not configured to overlap each other vertically.

17. The stacked semiconductor light emitting device for a display pixel according to claim 9, wherein a vertical length of the third electrode is longer than a vertical length of the second electrode.

18. The stacked semiconductor light emitting device for a display pixel according to claim 17, wherein a vertical length of the common electrode is longer than the vertical length of the third electrode.

19. The stacked semiconductor light emitting device for a display pixel according to claim 3, wherein the areas of the first, second, and third transparent conductive layers are the same.
